(19) United States
(12) Patent Application Publication
(10) Pub. No.: US 2010/0256934 A1
(43) Pub. Date: Oct. 7, 2010

(54) REPORTING CIRCUIT BREAKER AND SYSTEM

(76) Inventor: Thomas M. Rohrbaugh, Reston, VA (US)

Correspondence Address: ITALIA IP, 3500 WEST OLIVE AVE., SUITE 300, BURBANK, CA, 91505, US

(21) Appl. No.: 12/418,182

(22) Filed: Apr. 3, 2009

(51) Int. Cl. G01R 21/00; G01R 19/00

(52) U.S. Cl. 702/62; 324/76.11

(57) ABSTRACT

A novel load-reporting circuit breaker having load sensing and a wireless transmitter providing a corresponding load signal and an identification signal of the distribution panel(s) and circuit. A receiver common for several or all load-reporting circuit breakers provides a signal corresponding to the received individual circuit loads and corresponding identifications or address data, to an accounting device, e.g. computer that aggregates all loads for each user to which such load is allocated.

### FIELD OF THE INVENTION

This application relates generally to a power distributions systems and user billing, more specifically, to multi-user power distribution systems connected to single circuit breaker panels and the associated load reporting circuit breaker.

### BACKGROUND

The increasing demand for conservation of resources and accounting for the particular use of those resources, specifically electricity, encourages building owners to retrofit buildings with associated meters and corresponding individual electricity distribution panels each tenant or account, with the intent of back-charging the tenant for excessive power consumption. However, the power distribution methods outlined in the National Electric Code require particular methods and equipment which may not be available or cost-effective for retrofitting a multi-tenant building.

In commercial facilities, the building space is divided into smaller units for the individual tenants, for whom the power consumption should be billed accordingly. However, due to the constant turnover of tenants and the resulting continual renovation and redesign of building spaces make re-routing and re-allocation of power branch circuits to new or different distribution panels each to be dedicated to the particular tenant, necessary, significant and recurring expense and inconvenience, including interruptions to the other tenants.

### SUMMARY

The present invention provides a power distribution system providing multiple branch circuits from a common distribution panel to which different and individually billed tenants, users or loads are connected and corresponding different power consumption is accounted individually and/or as a total for multiple circuits for each tenant, user or load. Each branch circuit has a corresponding circuit breaker transmitting an individual identification or address and load power drain signal to be received by a receiver, sorted and allocated (e.g. according to a tenant allocation schedule), wherein each of several tenants can be billed for only the specific power distribution circuits associated with their building space. As the tenants' usage changes, the novel system according to the present invention provides flexibility to add or delete additional circuits from the accounting and billing without necessitating distribution panel changes.

One embodiment of the present invention further includes a novel load-reporting circuit breaker having load (typically current) sensing and a wireless transmitter providing a corresponding load signal and an address unique to the distribution panel(s) and circuit. A receiver common for several or all load-reporting circuit breakers provides a signal including the individual circuit loads and corresponding identifications or address data, to an accounting device, e.g. computer that aggregates all loads for each user to which such loads are allocated. As the tenant needs change, the allocation of circuits may similarly change with minimal and possibly no changes to the physical layout. Other load consumption information, e.g. common utilities that are separately monitored according to the present invention may be allocated to the individual tenants according to a predetermined schedule.

### BRIEF DESCRIPTION OF DRAWINGS

The drawings, when considered in connection with the following description, are presented for the purpose of facilitating an understanding of the subject matter sought to be protected.

FIG. 1 is plan view of one embodiment of the novel circuit breaker device as disclosed herein; and

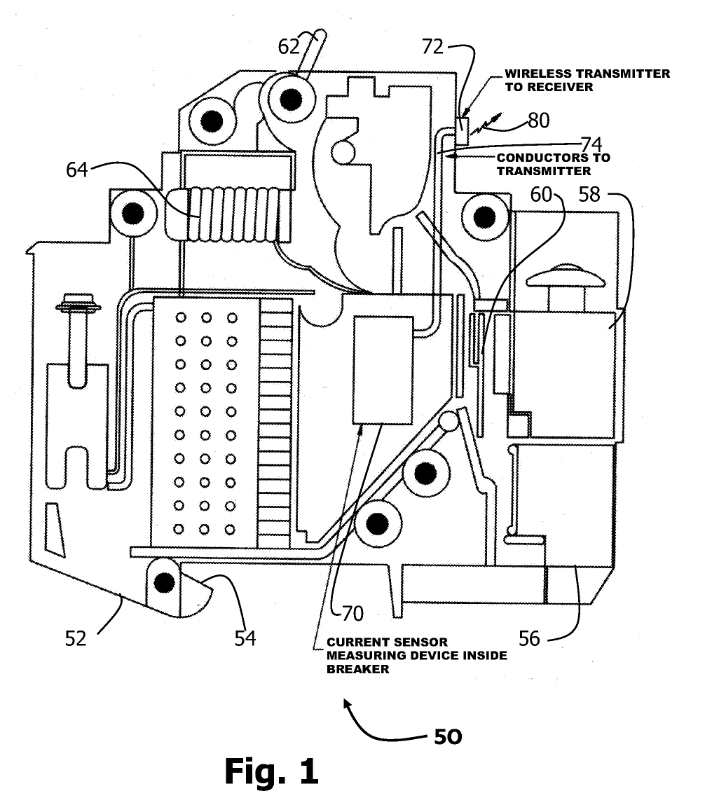

FIG. 2 is a block diagram of one embodiment of the system according to the present invention including the circuit breaker of FIG. 1.

### DETAILED DESCRIPTION

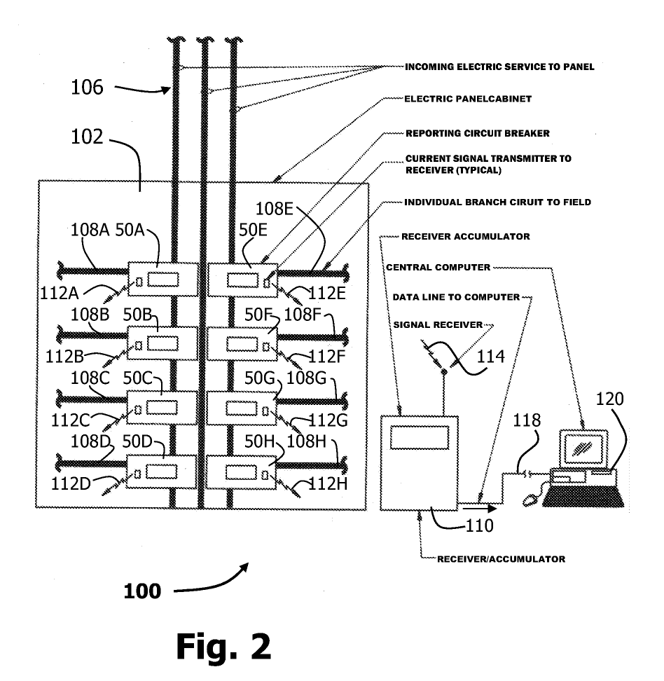

Referring to the exemplary embodiment 50 of the reporting circuit breaker according to the present invention, a housing 52 provides a circuit breaker which typically engages a distribution panel by protrusion 42, and a power distribution connector 56 (and ultimately connected to service 106, FIG. 2), which in turn is connected to branch connector 58 with movable internal contacts, including a bimetallic member 60, responsive to a manual actuator lever 62 and to the a solenoid 64, wherein the bimetallic member 60 and/or solenoid 64 are typically responsive to overload conditions and are connected to cause internal contacts to interrupt a circuit connection between power distribution connector 56 and branch circuit connector. According to the present invention, the exemplary circuit breaker 50 further includes a current sensor 70 disposed to provide a signal on connections 74 to a wireless transmitter 80 according to the power load imposed on the branch circuit by externally connected equipment (not shown). The transmitter 80 provides a wireless signal corresponding to the current sensor 70 signal and a identification signal unique to the particular circuit breaker 50 and therefore to the branch circuit to which the circuit breaker is connected, or unique to the tenant. Alternately, each circuit breaker may be programmable to have an identification corresponding to the particular tenant for which the connected branch circuit is associated (and therefore to be billed for power consumption). The current sensor typically comprises a commercially available current sensor, e.g. a current transformer, etc., capable of monitoring current in the range of current corresponding to the load rating of the circuit breaker 50.

In a typical application 100, the individual circuit breakers 50A-50H are disposed in a typical distribution panel 102 and are connected to a power source, such as from a power line pole, street connection, etc. via a service 106. The individual circuit breakers 50A-50H are connected to corresponding branch circuits 108A-108H having loads (not shown) which impose a power drain monitored by each circuit breaker 50A-50H and sending a corresponding wireless transmission 112A-112H to be received 114 by receiver/accumulator 110, which is in turn sends the data signals to a computer 120 via connection 118.

In exemplary one facility embodiment, circuits 108A, 108C and 108E may be associated with tenant A, while circuits 108B, 108D and 108F may be associated with tenant B, and so forth. In the case that each circuit breaker has unique individual identifications, the receiver/accumulator 110 or the computer 120 will be programmed to combine the signals, and with them the value for the power drawn in the associated branch circuits, together for the corresponding tenant, and further combine signals from other circuit breakers for other corresponding tenants. In the case where circuit breakers for the same tenant are programmed to provide an identical identification signal for the corresponding tenant, the receiver/accumulator 110 and/or the computer 120 provides a tenant accounting of power drain for received signals having the same identification.

The transmission and/or telemetry protocols, modes, formats, etc. used in the embodiments of the present invention may include available protocols, modes, formats, etc. available to those skilled in the art. Similarly, the transmitters 80, receiver/accumulator 110 and computer 120 may include transmitters, receiver and computer available to those skilled in the art. Moreover, the reporting circuit breakers according to the present invention may be located in a plurality of distribution panels and the resulting transmitted signals received by a common receiver, or plural receivers functioning as described above and having signals combined by or before the computer 120. Furthermore, other loads common to the facility or a number of tenants may be managed and accounted as a separate ‘tenant’. The present invention may apply to all voltages, phases, and Hertz. Modifications and substitutions made by one skilled in the art are within the scope of the present invention, which is not to be limited except by the claims that follow.

What is claimed is:

1. A circuit breaker, comprising:
a plurality of terminals;
a circuit closure device connected to provide a continuous electrical circuit between at least two of said plurality of terminals, and to interrupt said continuous electrical circuit in response to a current flow between said plurality of terminals in excess of a selected threshold value;
a current monitoring device providing a signal in response to a flow of current in said continuous electrical circuit; and
a transmitter providing a radiated signal in response to said flow of current and a corresponding circuit breaker identification.

2. The circuit breaker of claim 1, further including a housing including at least said circuit closure device, said current monitoring device and said transmitter.

3. The circuit breaker of claim 1, wherein said current monitoring device comprises a current transformer, current measuring device.

4. The circuit breaker of claim 1, wherein said transmitter provide a unique identification signal.

5. The circuit breaker of claim 1, wherein said transmitter provides an identification signal unique to a tenant.

6. A load monitoring system for multiple users receiving electrical power from at least one common circuit breaker panel, comprising:
a plurality of circuit breakers disposed within said common circuit breaker panel each connected to a corresponding circuit for diverse users, and each of said plurality of circuit breakers including a current signal transmitter including a wireless identification signal and including a signal corresponding to a flow of current through that circuit breaker;
a wireless signal receiver providing a received current signal and a corresponding circuit identification signal corresponding to each of said plurality of circuit breakers; and
a user load accounting device connected to receive said signals corresponding to the flow of current through circuits of a particular user.

7. The load monitoring system of claim 6, wherein said accounting device forms aggregate value of current used by said user.

8. The load monitoring system of claim 7, wherein each of said plurality of circuit breakers send unique identification signals, and said user load accounting device determines a total user load according to said unique identification signals.

9. The load monitoring system of claim 7, wherein each of said plurality of circuit breakers sends identification signals corresponding to a particular user, and said user load accounting device determines a total user load according to the identification signal corresponding to said particular user.

10. A method of managing electric power distribution in a facility, comprising:
providing a plurality of branch circuits from a common source to at least one facility tenant;
monitoring the power load of at least one of said branch circuit through a corresponding circuit breaker;
wirelessly transmitting a reporting signal corresponding to the monitored power load of said branch circuit and corresponding to a branch circuit identification signal;
receiving said reporting signal;
determining power consumption according to said reporting signal; and
accumulating an aggregate determined power from said determined power consumption over a period of time.

11. The method of claim 10, wherein said monitoring comprises monitoring a plurality of circuits, said step of determining comprises determining power consumption according to a plurality of reporting signals.

12. The method of claim 10, wherein
said providing a plurality of branch circuits comprises providing a plurality of branch circuits to at least two different facility tenants, and
said determining an aggregate determined power consumption comprises determining an aggregate determined power consumption for each facility tenant according to said reporting signal.

13. The method of claim 12, further including
transmitting a different identification signal for each branch circuit, and
identifying all identification signals for said facility tenant, and
determining aggregate power consumption according to said identification signals for said facility tenant

14. The method of claim 12, further including
wirelessly transmitting an identical identification signal for each branch circuit associated with said facility tenant, and
determining aggregate power consumption according to said identical identification signal for the corresponding said facility tenant.
